(19) United States
(12) Patent Application Publication
(10) Pub. No.: US 2019/0219613 A1
(43) Pub. Date: Jul. 18, 2019

(54) REDISTRIBUTION SYSTEM WITH HOMOGENOUS NON-CONDUCTIVE STRUCTURE AND METHOD OF MANUFACTURE THEREOF

(71) Applicant: AIS Technology, Inc., Pleasanton, CA (US)

(72) Inventors: Raymond W. Bae, Pleasanton, CA (US); Yingmei Zheng, San Jose, CA (US)

(21) Appl. No.: 15/870,669

(22) Filed: Jan. 12, 2018

(51) Int. Cl. G01R 1/073; H01L 23/498; H01L 23/15; H01L 21/48; H01L 23/14; G01R 3/00; G01R 31/28

(52) U.S. Cl. CPC G01R 1/07378; H01L 23/49838; H01L 23/49894; H01L 23/49827; H01L 24/16; H01L 21/486; H01L 23/145; G01R 3/00; G01R 31/2831; H01L 23/15

(57) ABSTRACT

A redistribution system includes: a substrate; a homogenous dielectric structure on the substrate, including a plurality of redistribution layers, wherein: the redistribution layers include a polymer layer and conductive traces; the redistribution layers are directly bonded to one another by cross-linking of polymer molecules within the polymer layer of one of the redistribution layers to the polymer molecules of the polymer layer in an adjacent instance of the redistribution layers; and routing traces, including the conductive traces, embedded in the homogenous dielectric structure.

### CROSS-REFERENCE TO RELATED APPLICATIONS

This application contains subject matter related to a concurrently filed U.S. patent application by Raymond W. Bae and Yingmei Zheng, titled “REDISTRIBUTION SYSTEM WITH UNIFORM CHARACTERISTIC MULTI-LAYERED HOMOGENOUS STRUCTURE AND METHOD OF MANUFACTURE THEREOF.” The related application is assigned to AIS Technology, Inc. and is identified by docket number 50-003. The subject matter thereof is incorporated herein by reference thereto.

This application contains subject matter related to a concurrently filed U.S. patent application by Raymond W. Bae and Yingmei Zheng, titled “REDISTRIBUTION SYSTEM WITH ROUTING LAYERS IN MULTI-LAYERED HOMOGENEOUS STRUCTURE AND A METHOD OF MANUFACTURING THEREOF.” The related application is assigned to AIS Technology, Inc. and is identified by docket number 50-004. The subject matter thereof is incorporated herein by reference thereto.

This application contains subject matter related to a concurrently filed U.S. patent application by Raymond W. Bae, titled “REDISTRIBUTION SYSTEM WITH DENSE PITCH AND COMPLEX CIRCUIT STRUCTURES IN MULTI-LAYERED HOMOGENEOUS STRUCTURE AND A METHOD OF MANUFACTURING THEREOF.” The related application is assigned to AIS Technology, Inc. and is identified by docket number 50-005. The subject matter thereof is incorporated herein by reference thereto.

### TECHNICAL FIELD

An embodiment of the present invention relates generally to a redistribution system.

### BACKGROUND

Modern consumer and industrial electronics, cellular phones, mobile devices, and computing systems, are providing increasing levels of functionality to support modern life including. Research and development in the existing technologies can take a myriad of different directions.

As users become more empowered with the growth of computing devices, new and old paradigms begin to take advantage of this new device space. There are many technological solutions to take advantage of this new device capability and device miniaturization. However, reliable testing of wafers through new devices has become a concern for manufactures.

Thus, a need still remains for a redistribution system for testing of wafers through devices. In view of the ever-increasing commercial competitive pressures, along with growing consumer expectations and the diminishing opportunities for meaningful product differentiation in the marketplace, it is increasingly critical that answers be found to these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides a redistribution system, including: a substrate; a homogenous dielectric structure on the substrate, including a plurality of redistribution layers, wherein: the redistribution layers include a polymer layer and conductive traces; the redistribution layers are directly bonded to one another by cross-linking of polymer molecules within the polymer layer of one of the redistribution layers to the polymer molecules of the polymer layer in an adjacent instance of the redistribution layers; and routing traces, including the conductive traces, embedded in the homogenous dielectric structure.

An embodiment of the present invention provides a method of manufacture of a redistribution system including: providing a substrate; forming a plurality of redistribution layers on the substrate, the redistributions layers including a polymer layer and conductive traces; forming a homogenous dielectric structure by cross-linking polymer molecules within the polymer layer of one of the redistribution layers to the polymer molecules of the polymer layer an adjacent instances of redistribution layers to directly bonded adjacent instances of the redistribution layers; and forming routing traces, embedded in the homogenous dielectric structure, from the conductive traces.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a schematic side view of an embodiment of a redistribution system.

FIG. 2 is a top view of the redistribution platform of FIG. 1 of a redistribution system.

FIG. 3 is cross-sectional view of the redistribution platform of FIG. 3 along line 2-2 of FIG. 2.

FIG. 4 is a top view of the substrate.

FIG. 5 is a cross-sectional view of the substrate of FIG. 4 along line 4-4 of FIG. 4.

FIG. 6 is the substrate of FIG. 4 with conductive traces formed thereon.

FIG. 7 is the structure of FIG. 6 in forming one of the redistribution layers of FIG. 4.

FIG. 8 is the structure of FIG. 7 in forming the redistribution platform of FIG. 1.

FIG. 9 is a flow chart of a method of manufacturing of a redistribution system in an embodiment of the present invention.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The designation and usage of the term first, second, third, etc. is for convenience and clarity and is not meant limit a particular order. The steps or processes described can be performed in any order to implement the claimed subject matter.

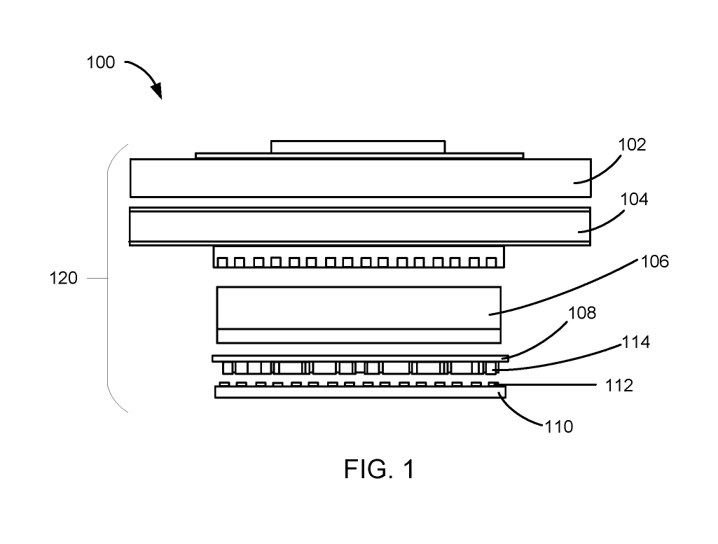

Referring now to FIG. 1, therein is shown a schematic side view of a redistribution system 100 in an embodiment of the present invention. The redistribution system 100 is a system for providing interconnection between devices. For example, the redistribution system 100 can be a component in a wafer testing system 120. The wafer testing system 100 can include a mechanical stiffener 102, a printed circuit board 104, a redistribution platform 106, and a probe card 108. The mechanical stiffener 102, the printed circuit board 104, the redistribution platform 106, and the probe card 108 are components for a system to test a semiconductor wafer 110. The semiconductor wafer 110 can be a processed silicon wafer with electronic components (not shown), such as circuits, integrated circuits, logic, integrated logic, or a combination thereof fabricated thereon.

The probe card 108 is an interface for contacting test locations on the semiconductor wafer 110, semiconductor dice 112, or a combination thereof. The probe card 108 can include probe heads 114 for contacting testing points or chip connecting pads (not shown) on the components formed on the surface of the semiconductor wafer 110, the die, or a combination thereof.

The redistribution platform 106 is structure for providing interconnection between two devices. For example, the redistribution platform 106 can be a space transformer, a package substrate for an integrated circuit package, a redistribution structure for a multi-die package, or a combination thereof. For illustrative purposes, the redistribution platform 106 is shown as a component that can provide electrical connectivity between the probe card 108 and the printed circuit board 104 of the wafer testing system 120. The redistribution platform 106 can provide electrical and functional connectivity between the semiconductor wafer 110, semiconductor dice 112, or a combination thereof for system testing, such as wafer testing, die testing, package testing, or inter-package testing.

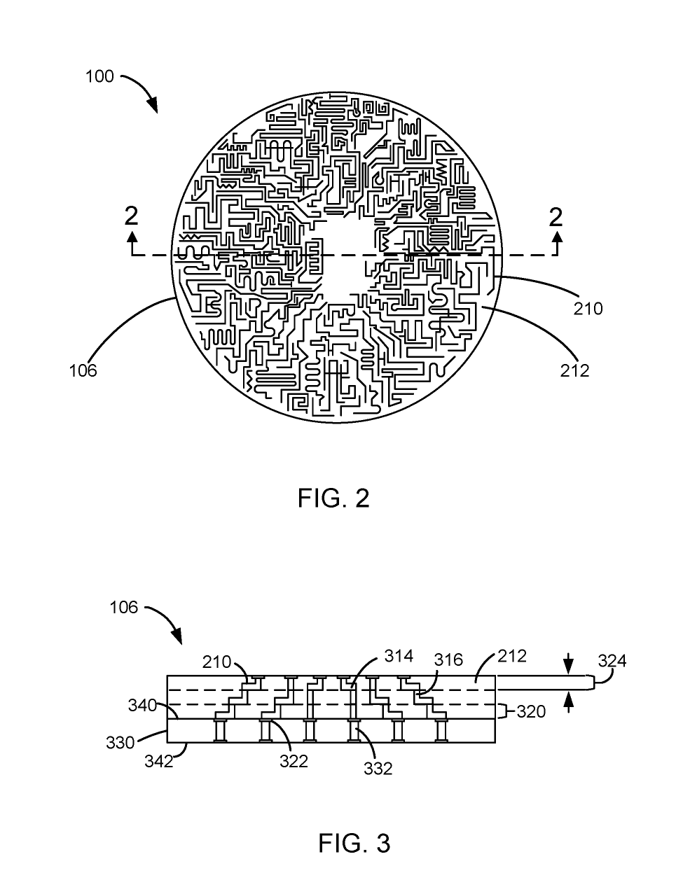

Referring now to FIG. 2, therein is shown a top view of the redistribution platform 106 of FIG. 1 of a redistribution system 200. The redistribution platform 106 can include routing traces 210 and a homogenous dielectric structure 212.

The routing traces 210 are one or more conductive structures that extend through the redistribution platform 106. The one or more routing traces 210 can be connected together either in their entirety to form one large routing trace 210, partially to form separate but connected routing traces 210, or can be isolated from one another to form individual and isolated routing traces 210 separate from any other routing trace 210.

The redistribution platform 106 of FIG. 1 can also provide a transition between the printed circuit board 104 FIG. 1 and the probe card 108 FIG. 1. For example, the routing traces 210 can be a multi-tiered structure for providing electrical connection. As a specific example, the routing traces 210 can provide connection pathway between the wider geometries and connection points on the printed circuit board 104 of FIG. 1 to the smaller geometries and connection points of the probe cards 108. The transition can include different geometries of electrical connection, different densities, different connection points, size of connections, number of routing traces 210, signal assignments, ground assignments, power assignments, or a combination thereof.

The routing traces 210 can include conductive material. For example, the routing traces 210 can include metals, such as elemental copper, silver, or gold, or metallic alloys, such as copper alloys, silver alloys, or gold alloys.

The routing traces 210 can be used to transmit electrical signals throughout the redistribution platform 106. For example, in one embodiment, the routing traces 210 can facilitate the transmission of electrical signals from the printed circuit board 104 to the probe card 108. The routing traces 210 can also provide shielding of electrical signals by surrounding other routing traces 210 used for signal transmission and provide grounds for the routing traces 210. For example, the routing traces 210 can achieve pitches 214 on the redistribution platform 106 on a scale ranging from less than or equal to 20 micrometers. As a result, the electrical signals transmitted through the one or more routing traces 210 can cause electromagnetic interference with one another. Pitch 214 refers to the shortest measure between the center to center distance between features, such as the routing traces 210, of the redistribution platform 106.

In one embodiment, one or more routing traces 210 can be used to provide grounding and to function as ground traces so that the signals along other routing traces 210 transmitting signals can be shielded from interfering electromagnetic signals in order to provide improved signal quality throughout the redistribution platform 106.

The homogenous dielectric structure 212 is a non-conductive material, such as a dielectric material, that encases the routing traces 210. The homogenous dielectric structure 212 can be an electrically insulating material that provides insulation between each of the routing traces 210. For example, the homogenous dielectric structure 212 can be a structure formed from a polymer material. The homogenous dielectric structure 212 can be transparent or translucent, enabling optical visibility of the routing traces 210 through the homogenous dielectric structure 212. Transparent or translucent refers to allowing light in the visible wavelength spectrum to pass through. As an example, an object can be visually seen, at least partially, through a translucent material. As another example, an object can be seen, potentially distinctly, through a transparent material. Details of the redistribution platform 106 will be discussed below.

Referring now to FIG. 3, therein is shown a cross-sectional view of the redistribution platform 106 of FIG. 2 along line 2-2 of FIG. 2. The cross-sectional view depicts the redistribution platform 106 including the homogenous dielectric structure 212, the routing traces 210, and a substrate 330.

The substrate 330 can be a rigid foundation or base layer for the redistribution system 200. The substrate 330 can be composed of an electrically insulating material, such as a ceramic based or polymer composite based material. The substrate 330 can include a substrate first side 340 and a substrate second side 342. The substrate first side 340 and the substrate second side 342 can be the opposing surfaces of the substrate 330 that facing away from one another.

The substrate 330 can include through substrate vias 332. The through substrate vias 332 are structures that extends from one surface of the substrate 330 to an opposing surface of the substrate. As an example, the through substrate vias 332 can be formed from electrically conductive material including metals, such as elemental copper, silver, or gold, or metallic alloys, such as copper alloys, silver alloys, or gold alloys.

The homogenous dielectric structure 212 can be formed from a plurality of redistribution layers 320, as shown by the dashed lines. The redistribution layers 320 are individual layers that have been chemically bonded to one another. Each of the redistribution layers 320 can include a portion of the routing traces 210 embedded therein.

The homogenous dielectric structure 212 is a uniform structure formed from a single material. For example, the homogenous dielectric structure 212 can be a homogenous polymer structure that does not include any interstitial material, such as fiber reinforcement. The lack of interstitial or embedded material enables the homogenous dielectric structure 212 to be translucent or transparent according to the properties of the dielectric material used to form the homogenous dielectric structure 212. Since the homogenous dielectric structure 212 is formed of a single material, the homogenous dielectric structure 212 can have uniform structural and thermal properties, such as a uniform coefficient of thermal expansion.

The routing traces 210 can extend from the substrate 330 through the homogenous dielectric structure 212. Portions of the routing traces 210 can be connected to components, such as contact pads 322, at the surface of the homogenous dielectric structure 212 facing away from the substrate 330. The component can provide electrical connection between the routing traces 210 to other devices, such as test devices including as the probe card 108 of FIG. 1. The routing traces 210 can be electrically connect with the through substrate vias 332 on the first side of the substrate 330.

The portion of the routing traces 210 in a particular instance of the redistribution layers 320 is a tier of the routing traces 210. Each tier of the routing traces 210 can include a trace planar portion 214, a trace interconnect portion 216, or a combination thereof. The trace planar portion 214 is the portion of the routing traces 210 that can provide routing or redistribution along a two dimensional plane that is parallel to the substrate first side 340 or the substrate second side 342.

The trace interconnect portion 342 is the portion of the routing traces 210 that can extend from the trace planar portion 316 in a direction that is perpendicular to the substrate first side 340 or the substrate second side 342. As an example, the trace interconnect portion 316 can provide connection to the other tiers of the routing traces 210.

As an example, the redistribution layers 320 can be formed to have a redistribution layer thickness 324. The redistribution layer thickness 324 can range from 10 micrometers to 60 micrometers or more. More specifically, the redistribution layer thickness 324 can range from 10 microns to 30 microns. Each of the redistribution layers 320 can have the same or similar values of the redistribution layer thickness 324 or different values of the redistribution layer thickness 324. The redistribution layer thickness 324 of the redistribution layers 320 can be measured in a direction that is perpendicular to the substrate first side 340 or the substrate second side 342.

The substrate 330 can provide additional rigid support for the redistribution platform 106. More specifically, for example, the substrate 330 can provide structural support and rigidity for the homogenous dielectric structure 212 and the routing traces 210. The through substrate vias 332 at the substrate second side 342 can be processed for electrical connection to other devices, such as the printed circuit board 104 of FIG. 1.

For illustrative purposes, the redistribution platform 106 is shown with the redistribution layers 320 formed only on the substrate first side 340, however, it is understood that the redistribution platform 106 can be configured differently. For example, the redistribution platform 106 can include the redistribution layers 320 formed on both the substrate first side 340 and the substrate second side 342.

As a further example, the substrate 330 can be the homogeneous dielectric structure 212 formed previously. In this example, substrate 330 can be removed so only the homogeneous dielectric structure 212 along with the routing traces 210 and structures formed with the routing traces 210 remains while another instance of the homogeneous dielectric structure 212 is formed. The multiple instances of the homogeneous dielectric structure 212 can be the same or different.

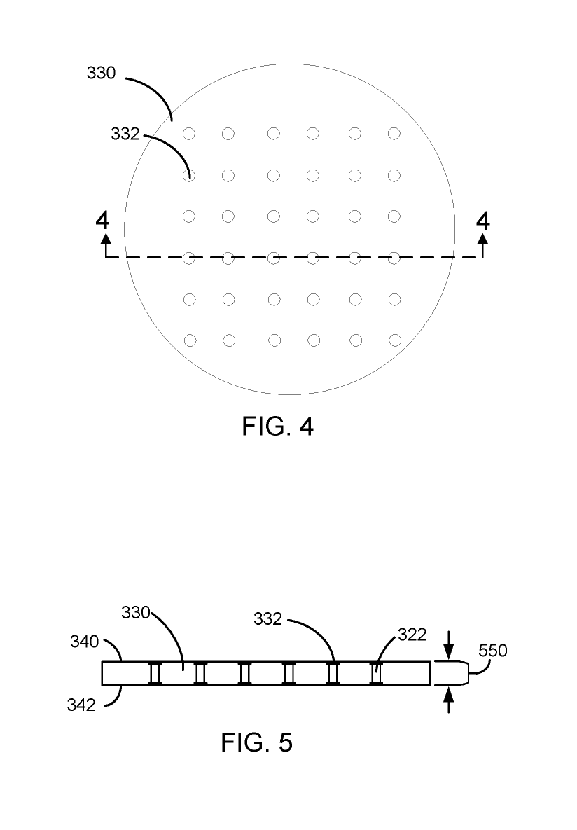

Referring now to FIG. 4, therein is shown a top view of the substrate 330. The substrate 330 can be provided as a prefabricated structure for forming the redistribution platform 106. The top view depicts a flat or planar surface of the substrate 330, such as the substrate first side 340 or the substrate second side 342, both of FIG. 3. The flat or planar surface of the substrate 330 can be used for attaching, connecting, mounting, or a combination thereof different components or material. For example, the substrate 330 can include optional pre-formed components such as metallic bonding or the contact pads 322 exposed at the flat or planar surface of the substrate 330 to facilitate electrical connection, such as connections to the routing traces 210 of FIG. 2. For illustrative purposes, the contact pads 322 are shown having a round or circular shape, although it is understood that the contact pads 322 can have a different shape. For example, the contact pads 322 can have a rectangular or elliptical shape.

The substrate 330 can be provided as a prefabricated structure for forming the redistribution platform 106. The substrate 330 can be formed from a number of different materials. For example, the substrate 330 can be formed from a ceramic based material, such as a high temperature co-fired ceramic (HTCC) or low temperature co-fired ceramic (LTCC). As another example, the substrate 330 can be formed from a polymer composite based material, such as a fiber reinforced polymer. As a specific example, the polymer based composite can include fiberglass reinforced epoxy laminates, such as Flame Retardant-4 (FR-4) grade printed circuit boards. As further example, the substrate 330 can be another instance or a design similar to the redistribution platform 106.

For illustrative purposes, the top view depicts the substrate 330 having a circular or round shape, although it is understood that the substrate 330 can have a different shape. For example, the substrate 330 can have an elliptical shape or a polygonal shape, such as a square, rectangle, or other polygonal shapes.

Referring now to FIG. 5, therein is shown a cross-sectional view of the substrate 330 of FIG. 4 along line 4-4 of FIG. 4. The cross-sectional view depicts a portion of the substrate 330 with the through substrate vias 332.

The substrate 330 can include the substrate first side 340 and a substrate second side 342. The substrate first side 340 and the substrate second side 342 can be the opposing surfaces of the substrate 330 that facing away from one another. The substrate first side 340 and the substrate second side 342 can be substantially parallel with one another. In general, a planar dimension, such as the width or diameter, of the substrate first side 340 and the substrate second side 342 can be greater than the substrate thickness, which can be measured as the distance between the substrate first side 340 and the substrate second side 342.

The substrate 330 can include the through substrate vias 332. The through substrate vias 332 are structures that extends from one surface of the substrate 330 to an opposing surface of the substrate. For example, the through substrate vias 332 can extend between the substrate first side 340 and the substrate second side 342 of the substrate 330.

As an example, the through substrate vias 332 can be formed from electrically conductive material, including metals, such as elemental copper, silver, or gold, or metallic alloys, such as copper alloys, silver alloys, or gold alloys. For illustrative purposes, the through substrate vias 332 are shown connected to the contact pads 322, however, it is understood that the contact pads 322 are optional and the through substrate vias 332 can exposed directly at the substrate first side 340, the substrate second side 342, or a combination thereof. Optionally, the portion of the through substrate vias 332 exposed at the substrate first side 340, the substrate second side 342, or a combination thereof, can be co-planar with the substrate first side 340 or the substrate second side 342, respectively.

The number, pattern, location, pitch, diameter, and size of the through substrate vias 332 are shown for illustrative purposes and are not drawn to scale. For example, the substrate 330 can include the through vias 332 having a pitch on a scale ranging from 10 to hundreds of micrometers. As another example, the diameter of the through vias 332 can be measured on a scale of tens of micrometers.

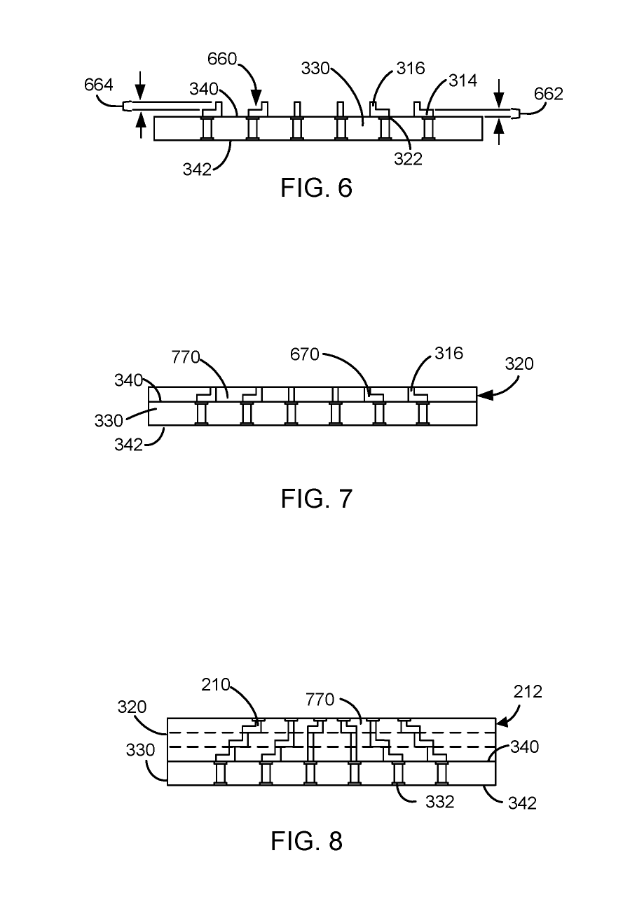

Referring now to FIG. 6, therein is shown the substrate 330 of FIG. 4 with conductive traces 660 formed thereon. The conductive traces 660 are a portion of an electrical routing system. More specifically, the conductive traces 660 can be a single tier of the routing trace 210 of FIG. 2. For example, the conductive traces 660 can be a single layer of a larger electrical routing system. As a specific example, the conductive traces 660 can be a portion of the routing trace 210 formed as a single layer.

The conductive traces 660 can be formed through a trace formation process, which can be a multi-phase process to pattern and form the conductive traces 660. For example, the trace formation process can include a masking phase, a seeding phase, a deposition phase, a planarization phase, and a mask removal phase.

The conductive traces 660 can be formed from conductive material that can include, metals, such as elemental copper, silver, or gold, or metallic alloys, such as copper alloys, silver alloys, or gold alloys. As a specific example, the conductive traces 660 can be composed of a material that is the same as or similar to the material of the through substrate vias 332.

In general, the conductive traces 660 can be formed on a two dimensional plane, such as a plane or surface that is parallel to the substrate first side 340, the substrate second side 342, or a combination thereof.

The conductive traces 660 can be formed to include the trace planar portion 314, the trace interconnect portion 316, or a combination thereof. For example, a first implementation of the trace formation process can be implemented to form the trace planar portion 314 and a subsequent implementation of the trace formation process can be implemented to form the trace interconnect portion 316 on the trace planar portion 314.

The trace planar portion 314 can include a planar portion thickness 662. The trace interconnect portion 316 can include an interconnection portion thickness 664. The planar portion thickness 662 and the interconnect portion thickness 664 can both be a linear dimension that is perpendicular to substrate first side 340 or the substrate second side 342. In general, the planar portion thickness 662 can be greater than the interconnect portion thickness 664. The sum of the planar portion thickness 662 and the interconnect portion thickness 664 can be the thickness of the conductive trace, which can be the same or similar to the redistribution layer thickness 324 of FIG. 3 for the corresponding instance of the redistribution layer 320.

The conductive traces 660 can be formed on the substrate 330. For example, the conductive traces 660 can be formed directly on the substrate first side 340 or the substrate second side 342. The conductive traces 660 can be formed to electrically connect with the through substrate vias 332. The conductive traces 660 can be formed by a number of different processes. For example, the conductive traces 660 can be formed by an electrolytic deposition process. Each of the conductive traces 660 can be formed to with different geometric patterns and dimensions, as illustrated in FIG. 2.

For illustrative purposes, the trace formation process is described in this figure for forming the conductive traces 660 directly on a surface of the substrate 330. However it is understood that the trace formation process described herein can be implemented to form the conductive traces 660 on other surfaces, such as a surface of the redistribution layers 320 of FIG. 3.

Referring now to FIG. 7, therein is shown the structure of FIG. 6 in forming one of the redistribution layers 320. The redistribution layers 320 can include the conductive traces 660 and a polymer layer 770. The polymer layers 770 are layers of a polymer material formed to cover the conductive traces 660. As a specific example, the polymer layer 770 can be an electrically insulating material which can cover portions of and electrically insulate each instance of the conductive traces 660.

The redistribution layers 320 can be formed from the structure of FIG. 6. In general, each of the polymer layers 770 can be formed through a polymer formation process. As an example, the polymer formation process can include an application phase, a curing phase, and a removal phase. In the application phase of the polymer buildup process, all or a portion of the conductive traces 660 can be covered by an application of a liquid dielectric precursor material (not shown).

The liquid dielectric precursor material can be an organic solution or organic suspension. For example, the liquid dielectric material can be a solution of monomer or oligomer molecules for a polymer, suspended or dissolved in a solvent. The liquid dielectric precursor material can be a solution that includes monomer or oligomer molecules as a precursor for one of a variety of different polymer materials. For example, the liquid dielectric precursor material can be a precursor for polyimide based polymers, epoxy based polymer, or other types of polymers. As a specific example, the liquid dielectric precursor material can include monomer or oligomer molecules that are capable of polymerization through a condensation reaction. In a further specific example, the liquid dielectric precursor material can include cross-linking or end-cap monomer units, which can be involved in cross-linking in a subsequent curing phase.

The end-cap monomer units are molecules that can stop or end the polymerization reaction of a particular molecule. More specifically, once each end of the a linear polymer molecule, or a polymer molecule that does not include branching into multiple polymer chains, has reacted with one of the end-cap monomer molecules, the polymer molecule can no longer react with the other non-end-cap monomer or oligomer molecules. In other words, once each end of the polymer molecule has reacted with an end-cap molecule, the polymer molecule can no longer increase in molecular weight outside of a cross-linking reaction, which will be discussed in detail below.

The liquid dielectric precursor material can be applied in a number of ways. For example, the liquid dielectric precursor material can be applied through a spin-coating process to cover the substrate 330, the conductive traces 660, or a combination thereof. As another example, the liquid dielectric precursor material can be applied through a method that can provide uniform distribution and thickness of the liquid dielectric precursor material across the substrate 330.

Following the application phase, the polymer formation process can proceed to the curing phase. In the curing phase, of the liquid dielectric precursor material can be heated to form an instance of the polymer layers 770. In general, the liquid dielectric precursor material can be heated to a polymerization temperature and for a time period that promotes polymer molecule chain building from the monomer or oligomer molecules. However, the polymerization temperature is different from a cross-linking temperature, which is a temperature at which cross-linking between the end-cap or cross-linking monomer molecules occurs. More specifically, the polymerization temperature can be a lower temperature than the temperature for cross-linking of an end-cap or cross-linking monomer molecules. The polymer molecules of the polymer layer 770 can be formed with a length or molecular weight that is statistically proportional to the number of monomer units and the end-cap units in the liquid dielectric precursor material.

Optionally, the curing phase can include a volatile removal or degassing phase to remove volatile components in the liquid dielectric precursor material. As an example, the volatile components can include evaporating solvent molecules or molecules formed during the polymerization of the liquid dielectric precursor material. The optional volatile removal phase can include a gradual temperature increase to or temperature hold near the boiling point of the solvent of the liquid dielectric precursor material. The optional volatile removal phase can include agitation of the liquid dielectric precursor material through vibration, such as ultrasonic vibration, during to facilitate removal of volatile components. The volatile removal phase can prevent void formation due to gasses trapped in the polymer layers 770 and at the interface between the conductive traces 660 and the polymer layers 770.

In the removal phase, a portion of the polymer layer 770 can be removed to form an instance of the redistribution layers 320. More specifically, portions of the polymer layer 770 facing away from the substrate 330 can be removed to expose the portions of the conductive traces 660 facing away from the substrate 330. The portions of the polymer layers 770 can be removed to expose the conductive traces 660 by a number of different processes. For example, the removal process can include chemical polishing, chemical grinding, mechanical polishing, mechanical grinding, or a combination thereof. The surface of the polymer layer 770 facing away from the substrate 330 can be processed to be co-planar with the portions of the conductive traces 660 exposed from the dielectric layer 882 and facing away from substrate 330. As an example, the redistribution layers 320 can be formed to have a thickness ranging 10 micrometers to 60 micrometers or more. In the example illustrated in FIG. 7, the thickness of the redistribution layers 320 can be measured from the interface between the substrate 330 and the instance of the redistribution layers 320, such as the substrate first side 340, to the surface of the instance of the redistribution layers 320 facing away from the substrate 330.

The polymer layer 770 can be transparent or translucent according to the cured properties of the liquid dielectric precursor material used to form the polymer layer 770. For example, the transparent or translucent property of the polymer layer 770 enables structures and objects within the polymer layer 770, such as the conductive traces 660 of the redistribution layers 320, to be visible and observable through the polymer layer. As a further example, the transparent or translucent property can enable viewing through the polymer layer 770 to see or visually observe and objects underneath or behind the polymer layer 770, such as the substrate 330 or previously formed instances of the redistribution layers 320.

Referring now to FIG. 8, therein is shown the structure of FIG. 7 in forming the redistribution platform 106 of FIG. 1. The cross-sectional view depicts the redistribution platform 106 formed following a sequentially formation of a plurality of the redistribution layers 320. For example, a further instance of the conductive traces 660 can be formed directly on surface of the polymer layer 770 of FIG. 7. To continue the example a further instance of the polymer layer 770 can be formed to cover the further instance of the conductive traces 660 and the previously formed instance of the redistribution layers 320. The process can be repeated to form a plurality of the redistribution layers 320 as depicted in FIG. 8.

Following the formation of the final instance of the redistribution layers 320, the plurality of the polymer layer 770 can be further processed to form the homogenous dielectric structure 212. For example, the homogenous dielectric structure 212 can be a homogenous polymer structure that does not include any interstitial material, such as fiber reinforcement. The lack of interstitial or embedded material enables the homogenous dielectric structure 212 to be translucent or transparent according to the properties of the dielectric material used to form the homogenous dielectric structure 212.

The homogenous dielectric structure 212 can be formed through cross-linking between the polymer layer 770 of the adjacent instances of the redistribution layers 320. More specifically, the homogenous dielectric structure 212 can be formed by heating the polymer layer 770 to a cross-linking temperature, or a temperature that facilitates or promotes the formation of chemical bonds between the end-caps throughout the polymer layer 770 and at the interface between adjacent instances of the polymer layer 770 to form a single continuous structure. The crosslinking temperature can be different from the temperature to form the polymer molecules of the polymer layer 770 as described in FIG. 7. In general, the cross-linking temperature is higher than that of the temperature for polymerization of the liquid dielectric precursor material of FIG. 7. The cross-linking temperature can vary based on the end-cap unit used for forming the cross-linking bonds between the polymer molecules.

It has been discovered that the homogenous dielectric structure 212 formed by cross-linking of polymer molecules between the redistribution layers 320 eliminates the need for an intervening bonding material. More specifically, forming of the cross-linking chemical bonds between the polymer molecules in the adjacent instances of the polymer layer 770 eliminates the need for adhesive or bonding material to form the homogenous dielectric structure 212.

The routing traces 210 can be exposed from a surface of the homogenous dielectric structure 212 facing away from the substrate 330. The exposed portions of the routing traces 210 can be further processed, such as by forming the contact pads 332 of FIG. 3, to provide electrical connection to other devices test devices, such as the probe card 108 of FIG. 1. The routing traces 210 can extend through the homogenous dielectric structure 212 and connect with the through vias 332 on the first side of the substrate 330.

The routing traces 210 embedded within the homogenous dielectric structure 212 can provide an interlocking function. The interlocking function between the routing traces 210 and the homogenous dielectric structure 212 can be formed as a physical feature. For example, during the application phase of FIG. 7 for the polymer layer 770 of FIG. 7, the liquid dielectric precursor material can fill in the spaces around and between the patterning of the conductive traces 660, as illustrated in FIG. 2. During the curing phase of FIG. 7, the liquid dielectric material can form a solid structure around the conductive traces 660, which locks the conductive traces 660 in place within the polymer layer 770 and forms an integrated interlocked structure for the homogenous dielectric structure 212.

The substrate 330 can provide additional rigid support for the redistribution platform 106. More specifically, the substrate 330 can provide structural support and rigidity for the homogenous dielectric structure 212 and the routing traces 210. The through substrate vias 332 at the substrate second side 342 can be processed for electrical connection to other devices, such as the printed circuit board 104 of FIG. 1.

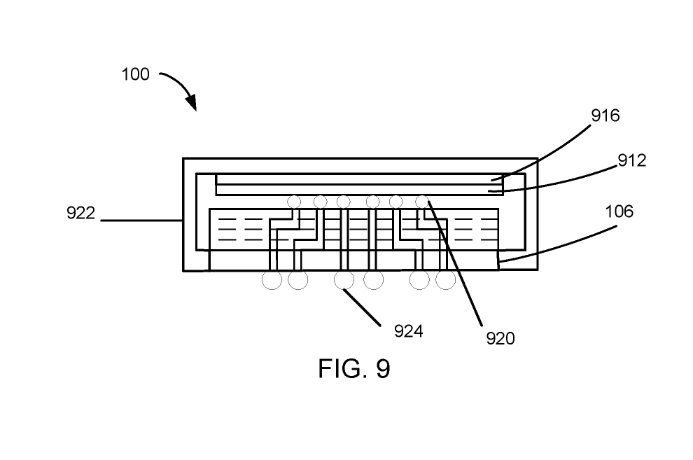

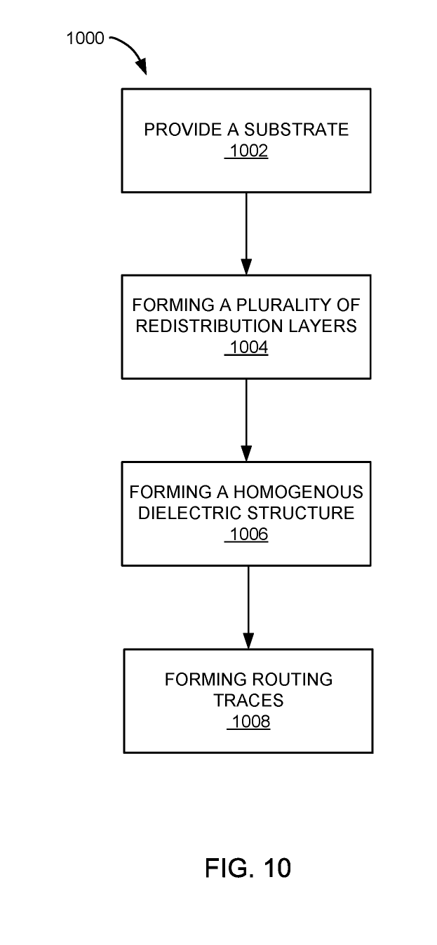

Referring now to FIG. 9, therein is shown a schematic side view of the redistribution system 100 of FIG. 2 in a further embodiment. The redistribution system 100 can be implemented as a package substrate in the further embodiment. In this example, the redistribution system 100 can include the redistribution platform 106 of FIG. 1, a die 912, a die attach adhesive 916, electrical interconnects 920, and a semiconductor cover 922.

In this example, the die 922 can be a semiconductor die, an integrated circuit, an optical device, or a combination thereof. The die 912 can be directly attached to the semiconductor cover 922 using the die attach adhesive 916. In this example, the semiconductor cover 912 can be a heat sink, a hermetically sealing encapsulant, a radio frequency shield, or a combination thereof.

Electrical interconnects 920 can provide electrical connections between the die 912 and the redistribution platform 106 by providing electrical connections between electronic components fabricated on the die 912, such as circuits, integrated circuits, logic, integrated logic, and electrical connections on one side of the redistribution platform 106. As an example, the electrical interconnects 920 can be solder balls or solder bumps.

Electrical interconnects 920 can be placed on a second side of the redistribution platform 106 and provide electrical connections between the redistribution platform 106 and external devices such as the probe card 108 of FIG. 1, the printed circuit board 104 of FIG. 1, or a combination thereof.

Referring now to FIG. 10, therein is shown a flow chart of a method 1000 of manufacturing of a redistribution system 100 in an embodiment of the present invention. The method 1000 includes: providing a substrate in a block 1002; forming a plurality of redistribution layers on the substrate, the redistributions layers including a polymer layer and conductive traces in a block 1004; forming a homogenous dielectric structure by cross-linking polymer molecules within the polymer layer of one of the redistribution layers to the polymer molecules of the polymer layer an adjacent instances of redistribution layers to directly bonded adjacent instances of the redistribution layers in a block 1006; and forming routing traces, embedded in the homogenous dielectric structure, from the conductive traces in a block 1008.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A redistribution system comprising:
a substrate;
a homogenous dielectric structure on the substrate, including a plurality of redistribution layers, wherein:
the redistribution layers include a polymer layer and conductive traces;
the redistribution layers are directly bonded to one another by cross-linking of polymer molecules within the polymer layer of one of the redistribution layers to the polymer molecules of the polymer layer in an adjacent instance of the redistribution layers; and
routing traces, including the conductive traces, embedded in the homogenous dielectric structure.

2. The redistribution system of claim 1, wherein the routing traces provide an interlocking function with the homogenous dielectric structure.

3. The redistribution system of claim 1, wherein:
the polymer molecules within polymer layer include end-caps; and
the end-caps of the polymer molecules are cross-linked with the end-caps of other instances of the polymer molecules.

4. The redistribution system of claim 1, wherein the polymer layer is a polyimide based polymer material.

5. The redistribution system of claim 1, wherein the polymer layer is an epoxy based polymer material.

6. The redistribution system of claim 1, wherein the homogenous dielectric structure does not include an adhesive material between the redistribution layers.

7. The redistribution system of claim 1, wherein the routing traces extend from the substrate to a surface of the homogenous dielectric structure facing away from the substrate.

8. The redistribution system of claim 1, wherein the substrate includes a through substrate via in the substrate and connected to the routing traces.

9. The redistribution system of claim 1, wherein the substrate is a ceramic substrate.

10. The redistribution system of claim 1, wherein the substrate is a polymer composite substrate.

11. A method of manufacturing a redistribution system comprising:
providing a substrate;
forming a plurality of redistribution layers on the substrate, the redistributions layers including a polymer layer and conductive traces;
forming a homogenous dielectric structure by cross-linking polymer molecules within the polymer layer of one of the redistribution layers to the polymer molecules of the polymer layer an adjacent instances of redistribution layers to directly bonded adjacent instances of the redistribution layers; and
forming routing traces, embedded in the homogenous dielectric structure, from the conductive traces.

12. The method of claim 11, wherein forming the routing traces includes forming an interlocking function with the homogenous dielectric structure.

13. The method of claim 11, forming a homogenous dielectric structure by cross-linking the polymer molecules within the polymer layer includes cross-linking between end-caps of the polymer molecules with the end-caps of other instances of the polymer molecules.

14. The method of claim 11, wherein forming the redistribution layers includes forming the redistribution layers with the polymer layer as a polyimide based polymer material.

15. The method of claim 11, wherein forming the redistribution layers includes forming the redistribution layers with the polymer layer as an epoxy based polymer material.

16. The method of claim 11, wherein forming the homogenous dielectric structure includes forming the homogenous dielectric structure without an adhesive material between the redistribution layers.

17. The method of claim 11, wherein forming the routing traces includes forming the routing traces extending from the substrate to a surface of the homogenous dielectric structure facing away from the substrate.

18. The method of claim 11, wherein:
providing the substrate includes providing the substrate including a through substrate vias; and
forming the redistribution layers include the conductive traces connected to the through substrate via.

19. The method of claim 11, wherein providing the substrate includes providing a ceramic substrate.

20. The method of claim 11, wherein providing the substrate includes providing a polymer composite substrate.
